(19) United States
(12) Patent Application Publication
(10) Pub. No.: US 2015/0116892 A1
(43) Pub. Date: Apr. 30, 2015

(54) MULTILAYER CERAMIC CAPACITOR AND BOARD HAVING THE SAME

(71) Applicant: SAMSUNG ELECTRO-MECHANICS CO., LTD., Suwon-Si (KR)

(72) Inventors: Min Cheol PARK, Suwon-Si (KR); Sang Soo PARK, Suwon-Si (KR)

(73) Assignee: SAMSUNG ELECTRO-MECHANICS CO., LTD., Suwon-Si (KR)

(21) Appl. No.: 14/257,806

(22) Filed: Apr. 21, 2014

(30) Foreign Application Priority Data
Oct. 31, 2013 (KR) 10-2013-0130786

(51) Int. Cl. H01G 4/40; H05K 1/16

(52) U.S. Cl. CPC H01G 4/40; H05K 1/162; H05K 1/167
USPC 361/275.3; 361/782

(57) ABSTRACT

A multilayer ceramic capacitor may include: a ceramic body including a plurality of dielectric layers; a capacitor part including a first internal electrode formed in the ceramic body and a second internal electrode formed in the ceramic body; a resistor part including a first internal connection conductor formed in the ceramic body and a second internal connection conductor formed in the ceramic body; a first dummy electrode formed in the ceramic body and a second dummy electrode formed in the ceramic body; and first to sixth external electrodes and the first and second internal connection conductors. The capacitor part and the resistor part may be connected in series to each other.

### CROSS-REFERENCE TO RELATED APPLICATION

This application claims the benefit of Korean Patent Application No. 10-2013-0130786 filed on Oct. 31, 2013, with the Korean Intellectual Property Office, the disclosure of which is incorporated herein by reference.

### BACKGROUND

The present disclosure relates to a multilayer ceramic capacitor and a board having the same.

Multilayer ceramic capacitors, multilayer chip electronic components, are chip-type condensers mounted on printed circuit boards of various electronic products such as display devices, for example, liquid crystal displays (LCDs), plasma display panels (PDPs), or the like, computers, smart phones, mobile phones, and the like, to be charged with or discharge electricity.

Since such a multilayer ceramic capacitor (MLCC) has advantages such as a small size, high capacitance, easiness of mounting, or the like, the multilayer ceramic capacitor may be used as a component of various electronic devices.

The multilayer ceramic capacitor may have a structure composed of a plurality of dielectric layers and internal electrodes alternately stacked between the dielectric layers and having different polarities.

Particularly, in a power supply device for a central processing unit (CPU) of a computer, or the like, voltage noise due to a rapid change in a load current may be generated during a process of supplying low voltage.

Therefore, the multilayer capacitor has been widely used in the power supply device as a capacitor for decoupling in order to suppress voltage noise.

The multilayer ceramic capacitor for decoupling should have low equivalent series inductance (ESL) as an operation frequency is increased. Various researches into technology for decreasing ESL have been actively conducted.

Further, in order to more stably supply power, the multilayer ceramic capacitor for decoupling should have controllable equivalent series resistance (ESR) characteristics.

In the case in which ESR of the multilayer ceramic capacitor is lower than the required level, an impedance peak at a parallel resonance frequency generated due to ESL of a capacitor and plane capacitance of a micro processor package may increase, and impedance at a series resonance frequency of a capacitor may excessively decrease.

Therefore, in order to implement flat impedance characteristics in a power distribution network, the ESR characteristics of the multilayer ceramic capacitor for decoupling are required to be easily controlled.

With regard to control of ESR, a scheme of using a material having high electrical resistance in external and internal electrodes may be considered. This scheme of changing a material may provide relatively high ESR characteristics while maintaining a low ESL structure according to the related art.

However, in the case of using a high resistant material in the external electrode, a localized heat spot caused by a current crowding phenomenon due to pin holes may be generated. Further, in the case of using a high resistant material in the internal electrode, in order to allow the material to correspond to a ceramic material for high capacitance, the material for an internal electrode should also be continuously changed.

Therefore, since the existing scheme for controlling ESR has disadvantages as described above, research into a multilayer ceramic capacitor capable of controlling ESR remains required.

In addition, in accordance with the recent trend toward rapid development of mobile terminals such as tablet personal computers (PCs), ultra books, or the like, microprocessors have also been converted into miniaturized and highly integrated products.

Therefore, an area of the printed circuit board has decreased, and amounting space of the capacitor for decoupling has also been limited. Multilayer ceramic capacitors capable of being appropriately used, satisfying such a limited mounting space, have been demanded thereby.

### RELATED ART DOCUMENT

Japanese Patent Laid-Open Publication No. 2012-138415

### SUMMARY

Some embodiments of the present disclosure may provide a multilayer ceramic capacitor and a board having the same.

According to some embodiments of the present disclosure, a multilayer ceramic capacitor may include: a ceramic body including a plurality of dielectric layers and having first and second main surfaces opposing each other, first and second side surfaces opposing each other, and first and second end surfaces opposing each other; a capacitor part including a first internal electrode formed in the ceramic body and having first and second leads exposed to the first main surface and a second internal electrode formed in the ceramic body and having third and fourth leads exposed to the second main surface; a resistor part including a first internal connection conductor formed in the ceramic body and having fifth to seventh leads exposed to the second main surface and a second internal connection conductor formed in the ceramic body and exposed to the first and second main surfaces; a first dummy electrode formed in the ceramic body and exposed to the first main surface and the first end surface of the ceramic body and a second dummy electrode formed in the ceramic body and exposed to the first main surface and the second end surface of the ceramic body; and first to sixth external electrodes formed on the first and second main surfaces of the ceramic body and electrically connected to the first and second internal electrodes and the first and second internal connection conductors, a first connection terminal formed on the first main surface and the first end surface of the ceramic body and connected to the first dummy electrode, and a second connection terminal formed on the first main surface and the second end surface of the ceramic body and connected to the second dummy electrode, wherein the capacitor part and the resistor part are connected in series to each other.

The first lead of the first internal electrode may be connected to the first external electrode, the second lead of the first internal electrode may be connected to the third external electrode, the third lead of the second internal electrode may be connected to the fourth external electrode, and the fourth lead of the second internal electrode may be connected to the sixth external electrode.

The first internal connection conductor may be connected to the second internal electrode via the fourth and sixth external electrodes and connected to the second internal connection conductor via the fifth external electrode.

One end of the second internal connection conductor may be connected to the first internal connection conductor via the fifth external electrode, and the other end thereof may be connected to the second external electrode.

According to some embodiments of the present disclosure, a multilayer ceramic capacitor may include: a ceramic body including a plurality of dielectric layers and having first and second main surfaces opposing each other, first and second side surfaces opposing each other, and first and second end surfaces opposing each other; a capacitor part including a first internal electrode formed in the ceramic body and having eighth and ninth leads exposed to the first main surface and a second internal electrode formed in the ceramic body and having a tenth lead exposed to the second main surface; a resistor part including a first internal connection conductor formed in the ceramic body and having eleventh to thirteenth leads exposed to the second main surface and a second internal connection conductor formed in the ceramic body and having a fourteenth lead exposed to the first main surface and fifteenth and sixteenth leads exposed to the second main surface; a first dummy electrode formed in the ceramic body and exposed to the first main surface and the first end surface of the ceramic body and a second dummy electrode formed in the ceramic body and exposed to the first main surface and the second end surface of the ceramic body; and first to sixth external electrodes formed on the first and second main surfaces of the ceramic body and electrically connected to the first and second internal electrodes and the first and second internal connection conductors, a first connection terminal formed on the first main surface and the first end surface of the ceramic body and connected to the first dummy electrode, and a second connection terminal formed on the first main surface and the second end surface of the ceramic body and connected to the second dummy electrode, wherein the capacitor part and the resistor part are connected in series to each other.

The eighth lead of the first internal electrode may be connected to the first external electrode, the ninth lead of the first internal electrode may be connected to the third external electrode, and the tenth lead of the second internal electrode may be connected to the fifth external electrode.

The first internal connection conductor may be connected to the second internal electrode via the fifth external electrode and connected to the second internal connection conductor via the fourth and sixth external electrodes.

The fifteenth and sixteenth leads of the second internal connection conductor may be connected to the first internal connection conductor via the fourth and sixth external electrodes, and the fourteenth lead thereof may be connected to the second external electrode.

According to some embodiments of the present disclosure, a multilayer ceramic capacitor may include: a ceramic body including a plurality of dielectric layers and having first and second main surfaces opposing each other, first and second side surfaces opposing each other, and first and second end surfaces opposing each other; a capacitor part including a first internal electrode formed in the ceramic body and having a seventeenth lead exposed to the first main surface and a second internal electrode formed in the ceramic body and having an eighteenth lead exposed to the second main surface; a resistor part including a first internal connection conductor formed in the ceramic body and having nineteenth to twenty-first leads exposed to the second main surface and two second internal connection conductors formed in the ceramic body and exposed to the first and second main surfaces; a first dummy electrode formed in the ceramic body and exposed to the first main surface and the first end surface of the ceramic body and a second dummy electrode formed in the ceramic body and exposed to the first main surface and the second end surface of the ceramic body; and first to sixth external electrodes formed on the first and second main surfaces of the ceramic body and electrically connected to the first and second internal electrodes and the first and second internal connection conductors, a first connection terminal formed on the first main surface and the first end surface of the ceramic body and connected to the first dummy electrode, and a second connection terminal formed on the first main surface and the second end surface of the ceramic body and connected to the second dummy electrode, wherein the capacitor part and the resistor part are connected in series to each other.

The seventeenth lead of the first internal electrode may be connected to the second external electrode, and the eighteenth lead of the second internal electrode may be connected to the fifth external electrode.

The first internal connection conductor may be connected to the second internal electrode via the fifth external electrode and connected to two second internal connection conductors via the fourth and sixth external electrodes.

One ends of two second internal connection conductors may be connected to the first internal connection conductor via the fourth and sixth external electrodes, and the other ends thereof may be connected to the first and third external electrodes.

According to some embodiments of the present disclosure, a multilayer ceramic capacitor may include: a ceramic body including a plurality of dielectric layers and having first and second main surfaces opposing each other, first and second side surfaces opposing each other, and first and second end surfaces opposing each other; a first internal electrode having a twenty-second lead exposed to the first main surface and a third internal electrode having a twenty-third lead exposed to the first main surface, the first and third internal electrodes being formed on one dielectric layer in the ceramic body, and a second internal electrode having a twenty-fourth lead exposed to the second main surface and a fourth internal electrode having a twenty-fifth lead exposed to the second main surface, the second and fourth internal electrodes being formed on another dielectric layer in the ceramic body; a first resistor part including a first internal connection conductor formed in the ceramic body and having twenty-sixth and twenty-seventh leads exposed to the second main surface, a second resistor part including a second internal connection conductor formed in the ceramic body and having twenty-eighth and twenty-ninth leads exposed to the second main surface, and a resistor part including a third internal connection conductor formed in the ceramic body and exposed to the first and second main surfaces; a first dummy electrode formed in the ceramic body and exposed to the first main surface and the first end surface of the ceramic body and a second dummy electrode formed in the ceramic body and exposed to the first main surface and the second end surface of the ceramic body; and first to sixth external electrodes formed on the first and second main surfaces of the ceramic body and electrically connected to the first and second internal electrodes and the first to third internal connection conductors, a first connection terminal formed on the first main surface and the first end surface of the ceramic body and connected to the first dummy electrode, and a second connection terminal formed on the first main surface and the second end surface of the ceramic body and connected to the second dummy electrode, wherein the first and second internal electrodes form a first capacitor part, and the third and fourth internal electrodes form a second capacitor part, the first capacitor part and the first resistor part being connected in series to each other, and the second capacitor part and the second resistor part being connected in series to each other.

The twenty-second lead of the first internal electrode may be connected to the first external electrode, the twenty-third lead of the third internal electrode may be connected to the third external electrode, the twenty-fourth lead of the second internal electrode may be connected to the fourth external electrode, and the twenty-fifth lead of the fourth internal electrode may be connected to the sixth external electrode.

The first internal connection conductor may be connected to the second internal electrode via the fourth external electrode and connected to the second internal connection conductor via the fifth external electrode.

The second internal connection conductor may be connected to the first internal connection conductor via the fifth external electrode and connected to the fourth internal electrode via the sixth external electrode.

One end of the third internal connection conductor may be connected to the first and second internal connection conductors via the fifth external electrode, and the other end thereof may be connected to the second external electrode.

According to some embodiments of the present disclosure, a board having a multilayer ceramic capacitor may include: a printed circuit board having first to fifth electrode pads formed thereon; and the multilayer ceramic capacitor as described above mounted on the printed circuit board.

The fourth electrode pad may contact the first connection terminal.

The fifth electrode pad may contact the second connection terminal.

The first and fourth electrode pads may contact each other, and the third and fifth electrode pads may contact each other.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is a perspective diagram of a multilayer ceramic capacitor according to a first exemplary embodiment of the present disclosure;

FIG. 2 is a plan diagram illustrating first and second internal electrodes applied to the multilayer ceramic capacitor shown in FIG. 1;

FIG. 3 is a plan diagram illustrating first and second internal connection conductors able to be used together with the first and second internal electrodes shown in FIG. 2;

FIG. 4 is an equivalent circuit diagram of the multilayer ceramic capacitor shown in FIG. 1;

FIG. 5 is a perspective diagram of a multilayer ceramic capacitor according to a second exemplary embodiment of the present disclosure;

FIG. 6 is a plan diagram illustrating first and second internal electrodes applied to the multilayer ceramic capacitor shown in FIG. 5;

FIG. 7 is a plan diagram illustrating first and second internal connection conductors able to be used together with the first and second internal electrodes shown in FIG. 6;

FIG. 8 is a perspective diagram of a multilayer ceramic capacitor according to a third exemplary embodiment of the present disclosure;

FIG. 9 is a plan diagram illustrating first and second internal electrodes applied to the multilayer ceramic capacitor shown in FIG. 8;

FIG. 10 is a plan diagram illustrating first and second internal connection conductors able to be used together with the first and second internal electrodes shown in FIG. 9;

FIG. 11 is a perspective diagram of a multilayer ceramic capacitor according to a fourth exemplary embodiment of the present disclosure;

FIG. 12 is a plan diagram illustrating first to fourth internal electrodes applied to the multilayer ceramic capacitor shown in FIG. 11;

FIG. 13 is a plan diagram illustrating first to third internal connection conductors able to be used together with the first to fourth internal electrodes shown in FIG. 12;

FIG. 14 is an equivalent circuit diagram of the multilayer ceramic capacitor shown in FIG. 11;

FIG. 15 is a perspective diagram illustrating a form in which the multilayer ceramic capacitor of FIG. 1 is mounted on a printed circuit board; and

FIG. 16 is a graph for comparing impedances in Inventive Example and Comparative Example.

### DETAILED DESCRIPTION

Exemplary embodiments of the present disclosure will now be described in detail with reference to the accompanying drawings.

The disclosure may, however, be exemplified in many different forms and should not be construed as being limited to the specific embodiments set forth herein. Rather, these embodiments are provided so that this disclosure will be thorough and complete, and will fully convey the scope of the disclosure to those skilled in the art.

In the drawings, the shapes and dimensions of elements may be exaggerated for clarity, and the same reference numerals will be used throughout to designate the same or like elements.

Directions of a hexahedron will be defined in order to clearly describe exemplary embodiments of the present disclosure. L, W and T shown in the accompanying drawings refer to a length direction, a width direction, and a thickness direction, respectively. Here, the thickness direction may be the same as a stacking direction in which dielectric layers are stacked.

Multilayer Ceramic Capacitor

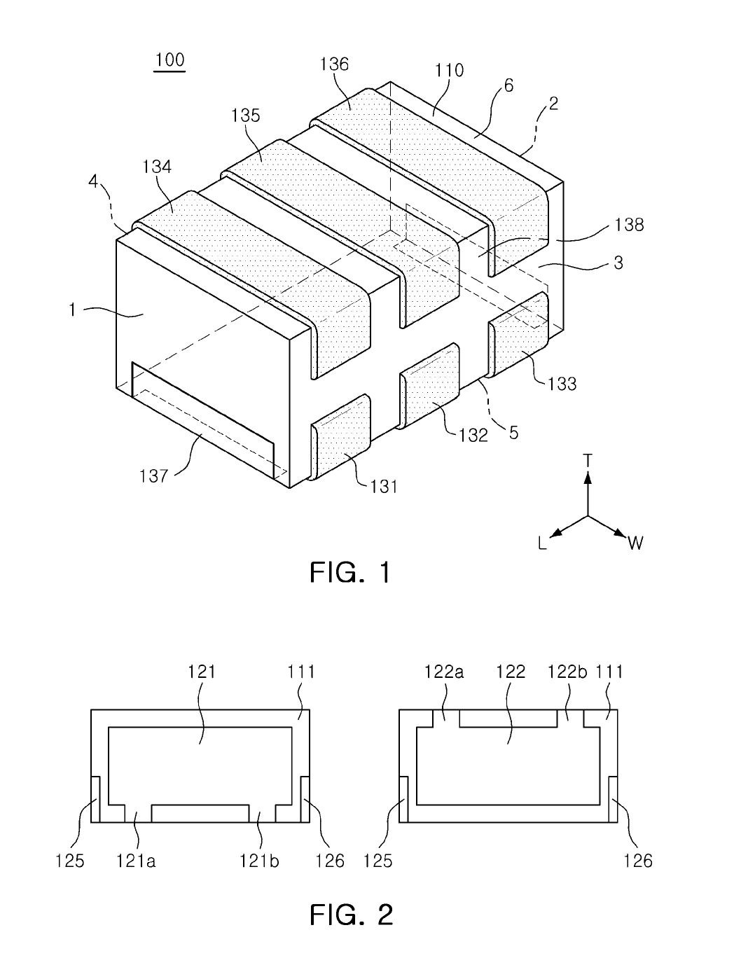

FIG. 1 is a perspective diagram of a multilayer ceramic capacitor according to a first exemplary embodiment of the present disclosure.

FIG. 2 is a plan diagram illustrating first and second internal electrodes applied to the multilayer ceramic capacitor shown in FIG. 1.

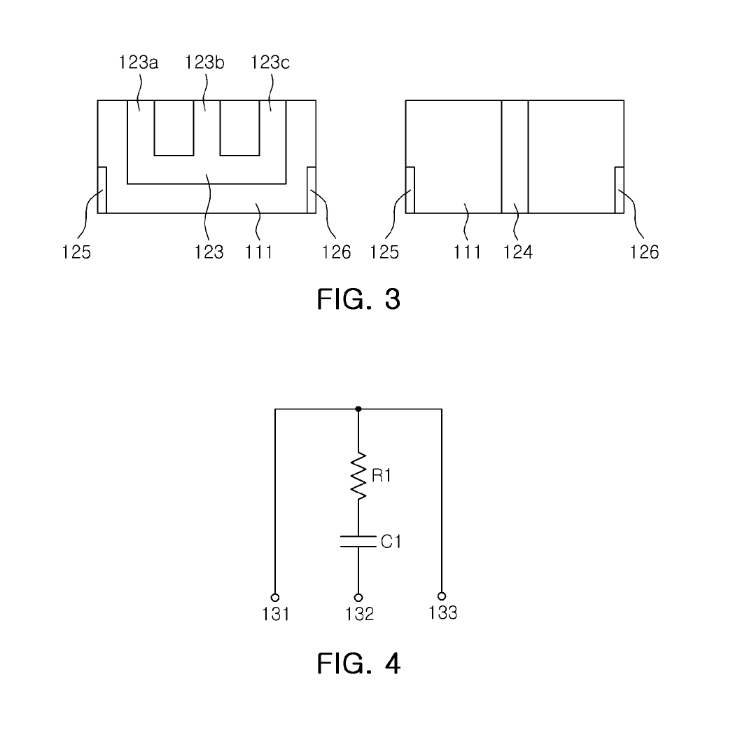

FIG. 3 is a plan diagram illustrating first and second internal connection conductors able to be used together with the first and second internal electrodes shown in FIG. 2.

Referring to FIGS. 1 through 3, the multilayer ceramic capacitor 100 according to the first exemplary embodiment of the present disclosure may include a ceramic body 110 including a plurality of dielectric layers 111 and having first and second main surfaces opposing each other, first and second side surfaces opposing each other, and first and second end surfaces opposing each other.

In this exemplary embodiment, the ceramic body 110 may have first and second main surfaces 5 and 6 opposing each other, and first and second side surfaces 3 and 4 and first and second end surfaces 1 and 2 that connect the first and second main surfaces to each other.

A shape of the ceramic body 110 is not particularly limited, but may be a hexahedral shape as illustrated in the drawings.

The ceramic body 110 may be formed by stacking the plurality of dielectric layers, and a plurality of internal electrodes 121 and 122 (sequentially first and second internal electrodes) may be disposed in the ceramic body 110 so as to be separated from each other with each of the dielectric layers interposed therebetween.

The plurality of dielectric layers 111 configuring the ceramic body 110 may be in a sintered state and be integrated with each other so as not to discern a boundary between dielectric layers adjacent to each other without using a scanning electron microscope (SEM).

The dielectric layer 111 may be formed by sintering a ceramic green sheet containing a ceramic powder, an organic solvent, and an organic binder. As the ceramic powder, a high k material, a barium titanate (BaTiO₃) based material, a strontium titanate (SrTiO₃) based material, or the like, may be used. However, the ceramic powder is not limited thereto.

The multilayer ceramic capacitor 100 may include a capacitor part including the first internal electrode 121 formed in the ceramic body 110 and having first and second leads 121a and 121b exposed to the first main surface 5 and the second internal electrode 122 formed in the ceramic body 110 and having third and fourth leads 122a and 122b exposed to the second main surface 6.

According to the first exemplary embodiment of the present disclosure, the first and second internal electrodes 121 and 122 may be formed of a conductive paste containing a conductive metal.

The conductive metal may be nickel (Ni), copper (Cu), palladium (Pd), or an alloy thereof, but is not limited thereto.

An internal electrode layer may be printed on a ceramic green sheet configuring the dielectric layer using the conductive paste by a printing method such as a screen printing method or a gravure printing method.

The ceramic green sheets having the internal electrode printed thereon may be alternately stacked and sintered, thereby forming the ceramic body.

In addition, the multilayer ceramic capacitor 100 may include a resistor part including a first internal connection conductor 123 formed in the ceramic body 110 and having fifth to seventh leads 123a to 123c exposed to the second main surface 6 and a second internal connection conductor 124 formed in the ceramic body 110 and exposed to the first and second main surfaces 5 and 6.

For example, the first and second internal connection conductors 123 and 124 may function as equivalent series resistance (ESR) in the multilayer ceramic capacitor, as the resistor part.

The first and second internal connection conductors 123 and 124 are not particularly limited but may be formed using, for example, a conductive paste containing a conductive metal, similarly to the first and second internal electrodes 121 and 122.

The conductive metal may be nickel (Ni), copper (Cu), palladium (Pd), or an alloy thereof, but is not limited thereto.

In addition, the multilayer ceramic capacitor 100 may include a first dummy electrode 125 formed in the ceramic body 110 and exposed to the first main surface 5 and the first end surface 1 of the ceramic body 110 and a second dummy electrode 126 formed in the ceramic body 110 and exposed to the first main surface 5 and the second end surface 2 of the ceramic body 110.

The first and second dummy electrodes 125 and 126 are not particularly limited but may be formed of, for example, a conductive paste containing a conductive metal, similarly to the first and second internal electrodes 121 and 122.

The conductive metal may be nickel (Ni), copper (Cu), palladium (Pd), or an alloy thereof, but is not limited thereto.

In addition, the multilayer ceramic capacitor 100 may include first to sixth external electrodes 131 to 136 formed on the first and second main surfaces 5 and 6 of the ceramic body and electrically connected to the first and second internal electrodes 121 and 122 and the first and second internal connection conductors 123 and 124.

The first to third external electrodes 131 to 133 may be disposed to be spaced apart from each other on the first main surface 5 of the ceramic body 110, and the fourth to sixth external electrodes 134 to 136 may be disposed to be spaced apart from each other on the second main surface 6 of the ceramic body.

According to the first exemplary embodiment of the present disclosure, a mounting surface of the multilayer ceramic capacitor 100 may be the first or second main surface 5 or 6 of the ceramic body 110.

For example, the multilayer ceramic capacitor according to the first exemplary embodiment of the present disclosure may be vertically mounted but is not limited thereto. The multilayer ceramic capacitor may be mounted in various forms.

Therefore, external electrodes contacting first to third electrode pads on a board having a multilayer ceramic capacitor to be described below may be the first to third external electrodes 131 to 133.

According to the first exemplary embodiment of the present disclosure, it may be understood that three external electrodes 134 to 136 except for the first to third external electrodes 131 to 133 used as external terminals for connection with a power line are used as external electrodes for controlling equivalent series resistance (ESR).

However, since the fourth to sixth external electrodes used as the external terminals may be optionally selected so as to be appropriate for the desired ESR characteristics, the external electrodes for controlling ESR are not particularly limited.

The fourth to sixth external electrodes 134 to 136 capable of being used as the external electrodes for controlling ESR may be positioned, as non-contact terminals not connected to the power line, on an upper surface of the multilayer ceramic capacitor, based on a mounting state.

For example, according to the first exemplary embodiment of the present disclosure, since the fourth to sixth external electrodes 134 to 136, the non-contact terminals, are formed on the upper surface of the multilayer ceramic capacitor rather than on a side surface thereof, downsizing may not be hindered by the non-contact terminal, whereby a product may be miniaturized.

The first to sixth external electrodes 131 to 136 may be formed using a conductive paste containing a conductive metal.

The conductive metal may be nickel (Ni), copper (Cu), tin (Sn), or an alloy thereof, but is not limited thereto.

The conductive paste may further contain an insulating material. The insulating material may be, for example, glass, but is not limited thereto.

A method of forming the first to sixth external electrodes 131 to 136 is not particularly limited. For example, the first to sixth external electrodes 131 to 136 may be formed on the ceramic body by a printing method, a dipping method, or other methods such as a plating method, or the like.

A plating layer may further be formed on the first to sixth external electrodes 131 to 136 later.

The multilayer ceramic capacitor 100 is a six-terminal capacitor having a total of six external electrodes, but the present disclosure is not limited thereto.

In addition, the multilayer ceramic capacitor 100 may include a first connection terminal 137 formed on the first main surface 5 and the first end surface 1 of the ceramic body 110 and connected to the first dummy electrode 125 and a second connection terminal 138 formed on the first main surface 5 and the second end surface 2 of the ceramic body 110 and connected to the second dummy electrode 126.

The first and second connection terminals 137 and 138 are formed on the first main surface and both end surfaces of the ceramic body, respectively, such that at the time of mounting a multilayer ceramic capacitor on a board as described below, directivity of the multilayer ceramic capacitor may be determined.

The first and second connection terminals 137 and 138 may be formed using a conductive metal.

The conductive metal may be nickel (Ni), copper (Cu), tin (Sn), or an alloy thereof, but is not limited thereto.

For example, the first and second connection terminals 137 and 138 may be formed by plating unlike the first to sixth external electrodes 131 to 136. Therefore, the first and second connection terminals 137 and 138 may not contain glass unlike the first to sixth external electrodes 131 to 136.

Meanwhile, the first and second connection terminals 137 and 138 may be connected, as plating layers, to the first and third external electrodes 131 and 133, respectively, but are not necessarily limited thereto.

Hereinafter, among the configurations of the multilayer ceramic capacitor 100 according to the first exemplary embodiment of the present disclosure, the first and second internal electrodes 121 and 122, the first and second internal connection conductors 123 and 124, and the first to sixth external electrodes 131 to 136 will be described in detail with reference to FIGS. 2 and 3.

The capacitor part may include the first internal electrode 121 formed in the ceramic body 110 and having the first and second leads 121a and 121b exposed to the first main surface 5 and the second internal electrode 122 formed in the ceramic body 110 and having the third and fourth leads 122a and 122b exposed to the second main surface 6 to thereby form capacitance.

The first lead 121a of the first internal electrode 121 may be connected to the first external electrode 131, the second lead 121b of the first internal electrode 121 may be connected to the third external electrode 133, the third lead 122a of the second internal electrode 122 may be connected to the fourth external electrode 134, and the fourth lead 122b of the second internal electrode 122 may be connected to the sixth external electrode 136, but the present disclosure is not limited thereto.

The capacitor part may be disposed in the ceramic body 110 without particular limitations, and in order to implement target capacitance, a plurality of capacitor parts may be stacked.

The first internal connection conductor 123 may be connected to the second internal electrode 122 via the fourth and sixth external electrodes 134 and 136 and connected to the second internal connection conductor 124 via the fifth external electrode 135.

The first internal connection conductor 123 may be connected to the fourth and sixth external electrodes 134 and 136 via the fifth and seventh leads 123a and 123c exposed to the second main surface 6 and be connected to the second internal electrode 122 connected to the fourth and sixth external electrodes 134 and 136.

Further, the first internal connection conductor 123 may be connected to the fifth external electrode 135 via the sixth lead 123b exposed to the second main surface 6 and be connected to the second internal connection conductor 124 exposed to the first and second main surfaces 5 and 6.

In the first exemplary embodiment of the present disclosure, one end of the second internal connection conductor 124 exposed to the second main surface 6 may be connected to the first internal connection conductor 123 via the fifth external electrode 135 and the other end thereof exposed to the first main surface 5 may be connected to the second external electrode 132.

The first and second internal electrodes 121 and 122 may be alternately disposed, having the dielectric layer 111 therebetween, together with the first and second internal connection conductors 123 and 124.

A single first internal electrode 121 and a single second internal electrode 122 are shown in FIG. 2, respectively, but in an actually applied embodiment, the number of internal electrodes may be plural.

Similarly, a single first internal connection conductor 123 and a single second internal connection conductor 124 are shown in FIG. 3, but the internal connection conductor having at least one polarity may be provided in plural.

Meanwhile, the internal electrode and the internal connection conductor may be stacked in the sequence shown in FIGS. 2 and 3, but may be stacked in various sequences, as needed.

The desired ESR characteristics may be further precisely controlled by changing a width, a length, and the number of stacked first and second internal connection conductors 123 and 124.

Pattern shapes of the first and second internal connection conductors 123 and 124 shown in FIG. 3 are only examples according to an exemplary embodiment of the present disclosure, and the first and second internal connection conductors 123 and 124 may have various pattern shapes in order to control ESR.

For example, the first and second internal connection conductors 123 and 124 may have the same pattern shapes as those of the first and second internal electrodes 121 and 122 shown in FIG. 2.

According to the first exemplary embodiment of the present disclosure, the resistor part may be formed by the first and second internal connection conductors 123 and 124, and ESR of the multilayer ceramic capacitor may be controlled by the resistor part.

For example, as described below, the capacitor part including the first and second internal electrodes 121 and 122 and the resistor part including the first and second internal connection conductors 123 and 124 may be connected in series to each other.

The equivalent series resistance (ESR) of the multilayer ceramic capacitor may be controlled by this serial connection.

Further, in this exemplary embodiment, the first and third external electrodes 131 and 133 may be used as external terminals for connection with a power line, and the second external electrode 132 may be connected to a ground.

Meanwhile, the fourth to sixth external electrodes 134 to 136, three external electrodes except for the first to third external electrodes 131 to 133, may be used as the external electrodes for controlling the ESR and understood as the non-contact terminals.

FIG. 4 is an equivalent circuit diagram of the multilayer ceramic capacitor shown in FIG. 1.

Referring to FIG. 4, the capacitor part C1 including the first and second internal electrodes 121 and 122 and the resistor part R1 including the first and second internal connection conductors 123 and 124 may be connected in series to each other.

The multilayer ceramic capacitor according to the first exemplary embodiment of the present disclosure may have one kind of resistor and one kind of capacitor and control a respective value of the resistor and the capacitor.

The multilayer ceramic capacitor according to the first exemplary embodiment of the present disclosure has a structure including the internal electrodes 121 and 122, the internal connection conductors 123 and 124, and the external electrodes 131 to 136, such that it may be easy to decrease and control impedance in a wider frequency range, and a mounting space and a cost may be decreased due to a decrease in the number of components, as compared to the existing structure.

In addition, as the capacitor is vertically mounted, the downsizing may not be hindered by the non-contact terminal, thereby miniaturizing a product.

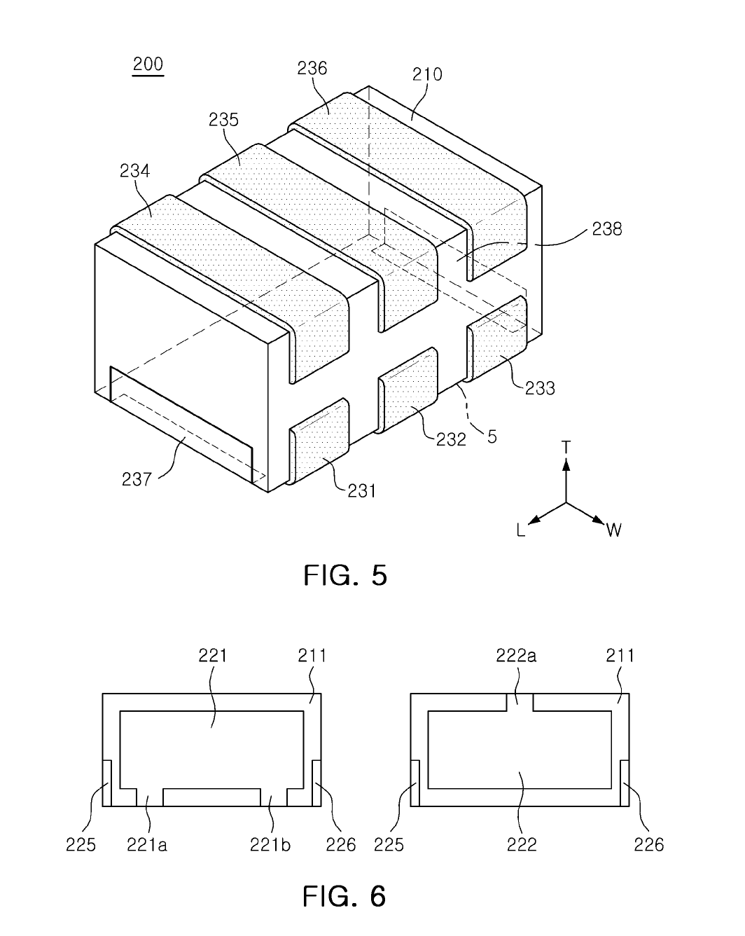

FIG. 5 is a perspective diagram of a multilayer ceramic capacitor according to a second exemplary embodiment of the present disclosure.

FIG. 6 is a plan diagram illustrating first and second internal electrodes applied to the multilayer ceramic capacitor shown in FIG. 5.

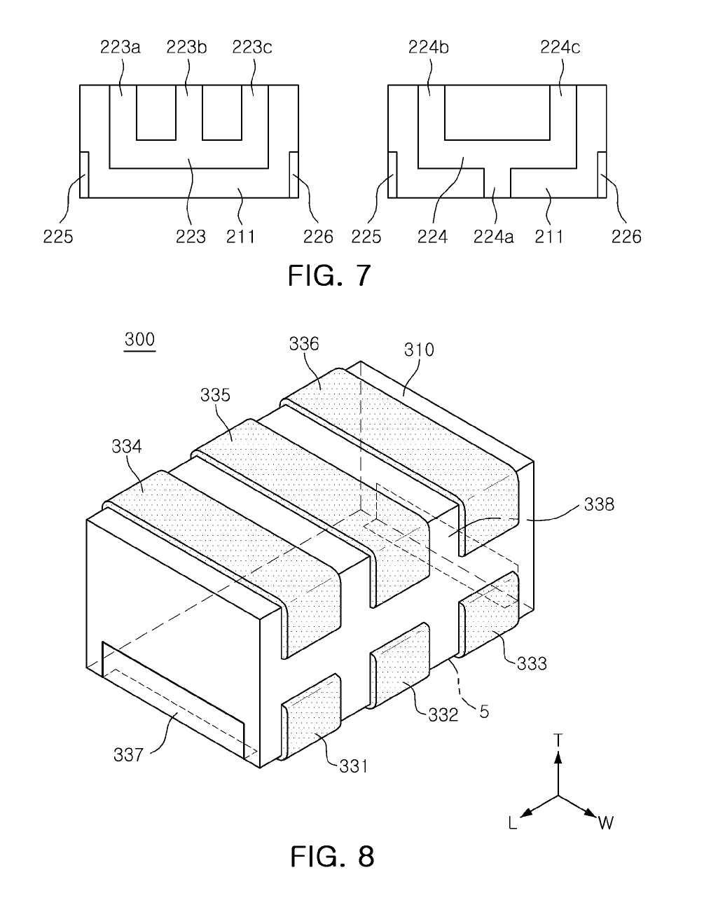

FIG. 7 is a plan diagram illustrating first and second internal connection conductors able to be used together with the first and second internal electrodes shown in FIG. 6.

Referring to FIGS. 5 through 7, a multilayer ceramic capacitor 200 according to a second exemplary embodiment of the present disclosure may include: a ceramic body 210 including a plurality of dielectric layers 211 and having first and second main surfaces opposing each other, first and second side surfaces opposing each other, and first and second end surfaces opposing each other; a capacitor part including a first internal electrode 221 formed in the ceramic body 210 and having eighth and ninth leads 221a and 221b exposed to the first main surface and a second internal electrode 222 formed in the ceramic body 210 and having a tenth lead 222a exposed to the second main surface; a resistor part including a first internal connection conductor 223 formed in the ceramic body 210 and having eleventh to thirteenth leads 223a to 223c exposed to the second main surface and a second internal connection conductor 224 formed in the ceramic body 210 and having a fourteenth lead 224a exposed to the first main surface and fifteenth and sixteenth leads 224b and 224c exposed to the second main surface; a first dummy electrode 225 formed in the ceramic body 210 and exposed to the first main surface and the first end surface of the ceramic body 210 and a second dummy electrode 226 formed in the ceramic body 210 and exposed to the first main surface and the second end surface of the ceramic body 210; and first to sixth external electrodes 231 to 236 formed on the first and second main surfaces of the ceramic body 210 and electrically connected to the first and second internal electrodes 221 and 222 and the first and second internal connection conductors 223 and 224, a first connection terminal 237 formed on the first main surface and the first end surface of the ceramic body 210 and connected to the first dummy electrode 225, and a second connection terminal 238 formed on the first main surface and the second end surface of the ceramic body 210 and connected to the second dummy electrode 226, wherein the capacitor part and the resistor part may be connected in series to each other.

In the second exemplary embodiment of the present disclosure, the eighth lead 221a of the first internal electrode 221 may be connected to the first external electrode 231, the ninth lead 221b of the first internal electrode 221 may be connected to the third external electrode 233, and the tenth lead 222a of the second internal electrode 222 may be connected to the fifth external electrode 235.

In the second exemplary embodiment of the present disclosure, the first internal connection conductor 223 may be connected to the second internal electrode 222 via the fifth external electrode 235 and connected to the second internal connection conductor 224 via the fourth and sixth external electrodes 234 and 236.

Further, the fifteenth and sixteenth leads 224b and 224c of the second internal connection conductor 224 may be connected to the first internal connection conductor 223 via the fourth and sixth external electrodes 234 and 236, and the fourteenth lead 224a thereof may be connected to the second external electrode 232.

Referring to FIGS. 6 and 7, the capacitor part including the first and second internal electrodes 221 and 222 and the resistor part including the first and second internal connection conductors 223 and 224 may be connected in series to each other.

Since other features of the multilayer ceramic capacitor according to the second exemplary embodiment of the present disclosure are the same as those of the above-mentioned multilayer ceramic capacitor according to the first exemplary embodiment of the present disclosure, a detailed description thereof will be omitted.

FIG. 8 is a perspective diagram of a multilayer ceramic capacitor according to a third exemplary embodiment of the present disclosure.

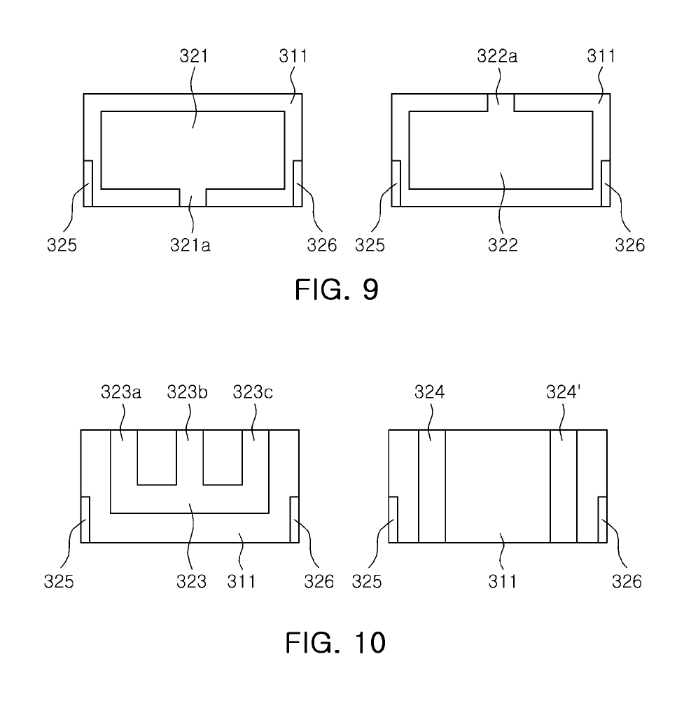

FIG. 9 is a plan diagram illustrating first and second internal electrodes applied to the multilayer ceramic capacitor shown in FIG. 8.

FIG. 10 is a plan diagram illustrating first and second internal connection conductors able to be used together with the first and second internal electrodes shown in FIG. 9.

Referring to FIGS. 8 through 10, a multilayer ceramic capacitor 300 according to a third exemplary embodiment of the present disclosure may include: a ceramic body 310 including a plurality of dielectric layers 311 and having first and second main surfaces opposing each other, first and second side surfaces opposing each other, and first and second end surfaces opposing each other; a capacitor part including a first internal electrode 321 formed in the ceramic body 310 and having a seventeenth lead 321a exposed to the first main surface and a second internal electrode 322 formed in the ceramic body 310 and having an eighteenth lead 322a exposed to the second main surface; a resistor part including a first internal connection conductor 323 formed in the ceramic body 310 and having nineteenth to twenty-first leads 323a to 323c exposed to the second main surface and two second internal connection conductors 324 and 324′ formed in the ceramic body 310 and exposed to the first and second main surfaces; a first dummy electrode 325 formed in the ceramic body 310 and exposed to the first main surface and the first end surface of the ceramic body 310 and a second dummy electrode 326 formed in the ceramic body 310 and exposed to the first main surface and the second end surface of the ceramic body 310; and first to sixth external electrodes 331 to 336 formed on the first and second main surfaces of the ceramic body 310 and electrically connected to the first and second internal electrodes 321 and 322 and the first and second internal connection conductors 323, 324, and 324′, a first connection terminal 337 formed on the first main surface and the first end surface of the ceramic body 310 and connected to the first dummy electrode 325, and a second connection terminal 338 formed on the first main surface and the second end surface of the ceramic body 310 and connected to the second dummy electrode 326, wherein the capacitor part and the resistor part may be connected in series to each other.

In the third exemplary embodiment of the present disclosure, the seventeenth lead 321a of the first internal electrode 321 may be connected to the second external electrode 332, and the eighteenth lead 322a of the second internal electrode 322 may be connected to the fifth external electrode 335.

In the third exemplary embodiment of the present disclosure, the first internal connection conductor 323 may be connected to the second internal electrode 322 via the fifth external electrode 335 and connected to two second internal connection conductors 324 and 324′ via the fourth and sixth external electrodes 334 and 336.

In the third exemplary embodiment of the present disclosure, one ends of two second internal connection conductor 324 and 324′ may be connected to the first internal connection conductor 323 via the fourth and sixth external electrodes 334 and 336, and the other ends thereof may be connected to the first and third external electrodes 331 and 333.

Referring to FIGS. 9 and 10, the capacitor part including the first and second internal electrodes 321 and 322 and the resistor part including the first and second internal connection conductors 323, 324, and 324′ may be connected in series to each other.

Since other features of the multilayer ceramic capacitor according to the third exemplary embodiment of the present disclosure are the same as those of the above-mentioned multilayer ceramic capacitor according to the first exemplary embodiment of the present disclosure, a detailed description thereof will be omitted.

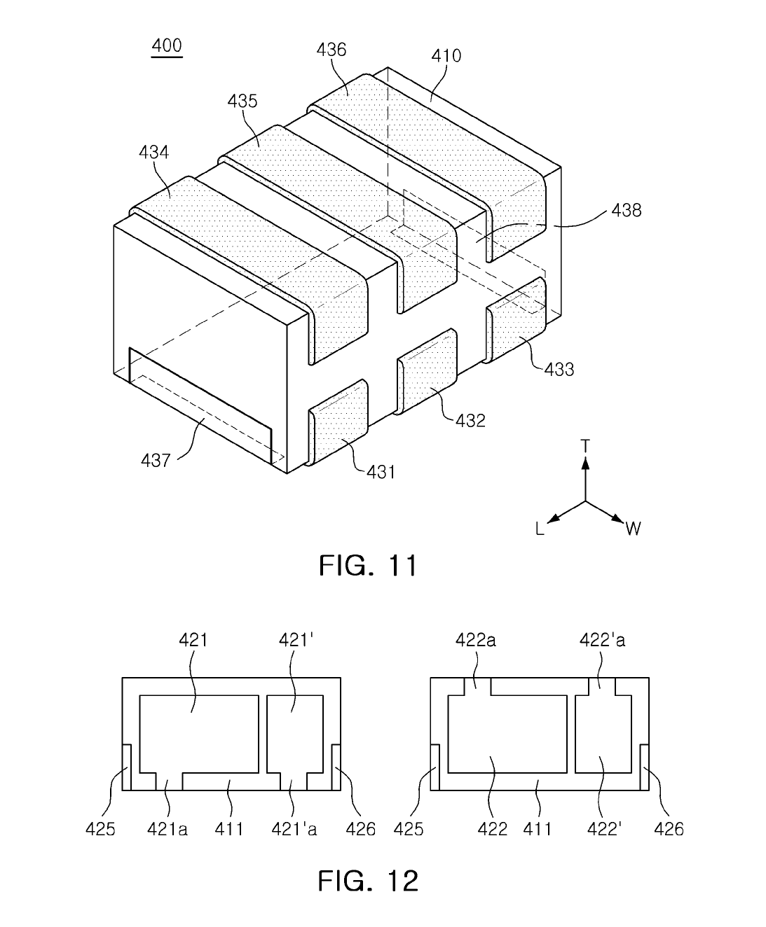

FIG. 11 is a perspective diagram of a multilayer ceramic capacitor according to a fourth exemplary embodiment of the present disclosure.

FIG. 12 is a plan diagram illustrating first to fourth internal electrodes applied to the multilayer ceramic capacitor shown in FIG. 11.

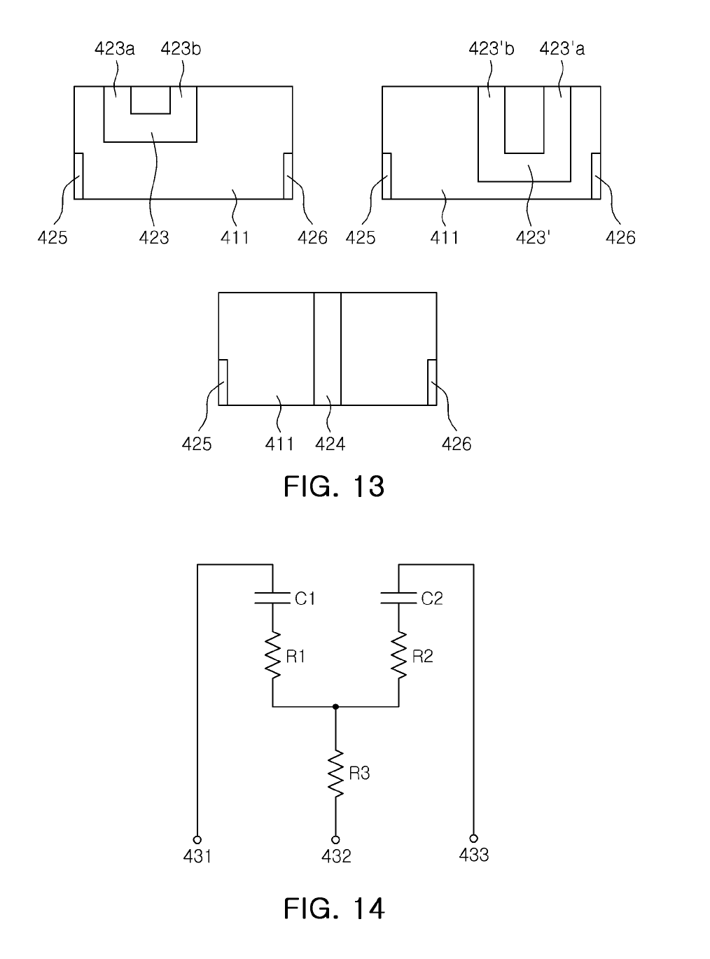

FIG. 13 is a plan diagram illustrating first to third internal connection conductors able to be used together with the first to fourth internal electrodes shown in FIG. 12.

FIG. 14 is an equivalent circuit diagram of the multilayer ceramic capacitor shown in FIG. 11.

Referring to FIGS. 11 through 14, a multilayer ceramic capacitor 400 according to a fourth exemplary embodiment of the present disclosure may include: a ceramic body 410 including a plurality of dielectric layers 411 and having first and second main surfaces opposing each other, first and second side surfaces opposing each other, and first and second end surfaces opposing each other; a first internal electrode 421 having a twenty-second lead 421a exposed to the first main surface and a third internal electrode 421′ having a twenty-third lead 421′a exposed to the first main surface, the first and third internal electrodes 421 and 421′ being formed on one dielectric layer 411 in the ceramic body 410, and a second internal electrode 422 having a twenty-fourth lead 422a exposed to the second main surface and a fourth internal electrode 422′ having a twenty-fifth lead 422′a exposed to the second main surface, the second and fourth internal electrodes 422 and 422′ being formed on another dielectric layer 411 in the ceramic body 410; a first resistor part R1 including a first internal connection conductor 423 formed in the ceramic body 410 and having twenty-sixth and twenty-seventh leads 423a and 423b exposed to the second main surface, a second resistor part R2 including a second internal connection conductor 423′ formed in the ceramic body 410 and having twenty-eighth and twenty-ninth leads 423′a and 423′b exposed to the second main surface, and a third resistor part R3 including a third internal connection conductor 424 formed in the ceramic body 410 and exposed to the first and second main surfaces; a first dummy electrode 425 formed in the ceramic body 410 and exposed to the first main surface and the first end surface of the ceramic body 410 and a second dummy electrode 426 formed in the ceramic body 410 and exposed to the first main surface and the second end surface of the ceramic body 410; and first to sixth external electrodes 431 to 436 formed on the first and second main surfaces of the ceramic body 410 and electrically connected to the first and second internal electrodes 421 and 422 and the first to third internal connection conductors 423, 423′, and 424, a first connection terminal 437 formed on the first main surface and the first end surface of the ceramic body 410 and connected to the first dummy electrode 425, and a second connection terminal 438 formed on the first main surface and the second end surface of the ceramic body 410 and connected to the second dummy electrode 426, wherein the first and second internal electrodes 421 and 422 form a first capacitor part C1, and the third and fourth internal electrodes 421′ and 422′ form a second capacitor part C2, the first capacitor part C1 and the first resistor part R1 being connected in series to each other, and the second capacitor part C2 and the second resistor part R2 being connected in series to each other.

In the fourth exemplary embodiment, the twenty-second lead 421a of the first internal electrode 421 may be connected to the first external electrode 431, the twenty-third lead 421′a of the third internal electrode 421′ may be connected to the third external electrode 433, the twenty-fourth lead 422a of the second internal electrode 422 may be connected to the fourth external electrode 434, and the twenty-fifth lead 422′a of the fourth internal electrode 422′ may be connected to the sixth external electrode 436.

In the fourth exemplary embodiment of the present disclosure, the first internal connection conductor 423 may be connected to the second internal electrode 422 via the fourth external electrode 434 and connected to the second internal connection conductor 423′ via the fifth external electrode 435.

In the fourth exemplary embodiment of the present disclosure, the second internal connection conductor 423′ may be connected to the first internal connection conductor 423 via the fifth external electrode 435 and connected to the fourth internal electrode 422′ via the sixth external electrode 436.

In the fourth exemplary embodiment of the present disclosure, one end of the third internal connection conductor 424 may be connected to the first and second internal connection conductors 423 and 423′ via the fifth external electrode 435, and the other end thereof may be connected to the second external electrode 432.

Referring to FIG. 14, the first capacitor part C1 and the first resistor part R1 may be connected in series to each other, and the second capacitor part C2 and the second resistor part R2 may be connected in series to each other.

Further, the first and second resistor parts R1 and R2 may be connected in series to the third resistor part R3.

In addition, the first and second capacitor parts C1 and C2 may be connected in parallel to each other.

Since other features of the multilayer ceramic capacitor according to the fourth exemplary embodiment of the present disclosure are the same as those of the above-mentioned multilayer ceramic capacitor according to the first exemplary embodiment of the present disclosure, a detailed description thereof will be omitted.

Board Having Multilayer Ceramic Capacitor

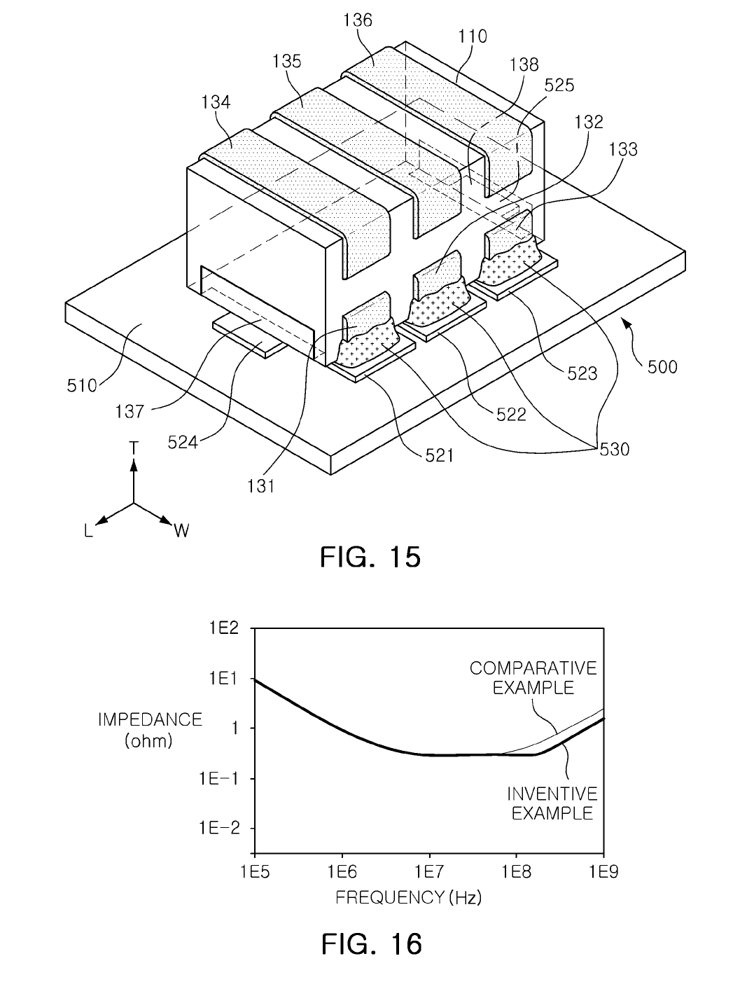

FIG. 15 is a perspective diagram illustrating a form in which the multilayer ceramic capacitor of FIG. 1 is mounted on a printed circuit board.

Referring to FIG. 15, a board 500 having a multilayer ceramic capacitor 100 according to the exemplary embodiment of the present disclosure may include a printed circuit board 510 on which the multilayer ceramic capacitor 100 is vertically mounted and first to fifth electrode pads 521 to 525 formed on the printed circuit board 510 so as to be spaced apart from one another.

The multilayer ceramic capacitor 100 may be electrically connected to the printed circuit board 510 by soldering 530 in a state in which the first to third external electrodes 131 to 133 are positioned on the first to third electrode pads 521 to 523 so as to contact each other, respectively.

The first connection terminal 137 may be electrically connected to the printed circuit board 510 by the soldering 530 in a state in which it is positioned on the fourth electrode pad 524 so as to contact each other.

The second connection terminal 138 may be electrically connected to the printed circuit board 510 by the soldering 530 in a state in which it is positioned on the fifth electrode pad 525 so as to contact each other.

Meanwhile, the first and fourth electrode pads 521 and 524 may contact each other, and the third and fifth electrode pads 523 and 525 may contact each other, but the present disclosure is not limited thereto.

A description of other features overlapped with those of the above-mentioned multilayer ceramic capacitor according to the first exemplary embodiment of the present disclosure will be omitted.

FIG. 16 is a graph for comparing impedances in Inventive Example and Comparative Example.

Referring to FIG. 16, it may be appreciated that in the multilayer ceramic capacitor according to an exemplary embodiment of the present disclosure, impedance may have a flat shape in a relatively wide frequency region and the impedance may be decreased, as compared to a multilayer ceramic capacitor according to the related art in Comparative Example.

According to some embodiments of the present disclosure, the multilayer ceramic capacitor may include the capacitor part and the resistor part and control the value of each of the capacitor part and the resistor part.

Therefore, as compared to the structure according to the related art, it may be easy to decrease and control the impedance in a relatively wide frequency region, and as the number of components may be decreased, the mounting space and the cost may be decreased.

In addition, as the capacitor is vertically mounted, the downsizing may not be hindered by the non-contact terminal, thereby miniaturizing a product.

While exemplary embodiments have been shown and described above, it will be apparent to those skilled in the art that modifications and variations could be made without departing from the spirit and scope of the present disclosure as defined by the appended claims.

What is claimed is:

1. A multilayer ceramic capacitor comprising:
a ceramic body including a plurality of dielectric layers, first and second main surfaces opposing each other, first and second side surfaces opposing each other, and first and second end surfaces opposing each other;
a capacitor part including a first internal electrode formed in the ceramic body and having first and second leads exposed to the first main surface and a second internal electrode formed in the ceramic body and having third and fourth leads exposed to the second main surface;
a resistor part including a first internal connection conductor formed in the ceramic body and having fifth to seventh leads exposed to the second main surface and a second internal connection conductor formed in the ceramic body and exposed to the first and second main surfaces;
a first dummy electrode formed in the ceramic body and exposed to the first main surface and the first end surface of the ceramic body and a second dummy electrode formed in the ceramic body and exposed to the first main surface and the second end surface of the ceramic body; and
first to sixth external electrodes formed on the first and second main surfaces of the ceramic body and electrically connected to the first and second internal electrodes and the first and second internal connection conductors, a first connection terminal formed on the first main surface and the first end surface of the ceramic body and connected to the first dummy electrode, and a second connection terminal formed on the first main surface and the second end surface of the ceramic body and connected to the second dummy electrode,
wherein the capacitor part and the resistor part are connected in series to each other.

2. The multilayer ceramic capacitor of claim 1, wherein the first lead of the first internal electrode is connected to the first external electrode, the second lead of the first internal electrode is connected to the third external electrode, the third lead of the second internal electrode is connected to the fourth external electrode, and the fourth lead of the second internal electrode is connected to the sixth external electrode.

3. The multilayer ceramic capacitor of claim 2, wherein the first internal connection conductor is connected to the second internal electrode via the fourth and sixth external electrodes and connected to the second internal connection conductor via the fifth external electrode.

4. The multilayer ceramic capacitor of claim 2, wherein one end of the second internal connection conductor is connected to the first internal connection conductor via the fifth external electrode, and the other end thereof is connected to the second external electrode.

5. A multilayer ceramic capacitor comprising:
a ceramic body including a plurality of dielectric layers and having first and second main surfaces opposing each other, first and second side surfaces opposing each other, and first and second end surfaces opposing each other;
a capacitor part including a first internal electrode formed in the ceramic body and having eighth and ninth leads exposed to the first main surface and a second internal electrode formed in the ceramic body and having a tenth lead exposed to the second main surface;
a resistor part including a first internal connection conductor formed in the ceramic body and having eleventh to thirteenth leads exposed to the second main surface and a second internal connection conductor formed in the ceramic body and having a fourteenth lead exposed to the first main surface and fifteenth and sixteenth leads exposed to the second main surface;
a first dummy electrode formed in the ceramic body and exposed to the first main surface and the first end surface of the ceramic body and a second dummy electrode formed in the ceramic body and exposed to the first main surface and the second end surface of the ceramic body; and
first to sixth external electrodes formed on the first and second main surfaces of the ceramic body and electrically connected to the first and second internal electrodes and the first and second internal connection conductors, a first connection terminal formed on the first main surface and the first end surface of the ceramic body and connected to the first dummy electrode, and a second connection terminal formed on the first main surface and the second end surface of the ceramic body and connected to the second dummy electrode,
wherein the capacitor part and the resistor part are connected in series to each other.

6. The multilayer ceramic capacitor of claim 5, wherein the eighth lead of the first internal electrode is connected to the first external electrode, the ninth lead of the first internal electrode is connected to the third external electrode, and the tenth lead of the second internal electrode is connected to the fifth external electrode.

7. The multilayer ceramic capacitor of claim 6, wherein the first internal connection conductor is connected to the second internal electrode via the fifth external electrode and connected to the second internal connection conductor via the fourth and sixth external electrodes.

8. The multilayer ceramic capacitor of claim 6, wherein fifteenth and sixteenth leads of the second internal connection conductor are connected to the first internal connection conductor via the fourth and sixth external electrodes, and the fourteenth lead of the second internal connection conductor is connected to the second external electrode.

9. A multilayer ceramic capacitor comprising:
a ceramic body including a plurality of dielectric layers and having first and second main surfaces opposing each other, first and second side surfaces opposing each other, and first and second end surfaces opposing each other;
a capacitor part including a first internal electrode formed in the ceramic body and having a seventeenth lead exposed to the first main surface and a second internal electrode formed in the ceramic body and having an eighteenth lead exposed to the second main surface;
a resistor part including a first internal connection conductor formed in the ceramic body and having nineteenth to twenty-first leads exposed to the second main surface and two second internal connection conductors formed in the ceramic body and exposed to the first and second main surfaces;
a first dummy electrode formed in the ceramic body and exposed to the first main surface and the first end surface of the ceramic body and a second dummy electrode formed in the ceramic body and exposed to the first main surface and the second end surface of the ceramic body; and
first to sixth external electrodes formed on the first and second main surfaces of the ceramic body and electrically connected to the first and second internal electrodes and the first and second internal connection conductors, a first connection terminal formed on the first main surface and the first end surface of the ceramic body and connected to the first dummy electrode, and a second connection terminal formed on the first main surface and the second end surface of the ceramic body and connected to the second dummy electrode,
wherein the capacitor part and the resistor part are connected in series to each other.

10. The multilayer ceramic capacitor of claim 9, wherein the seventeenth lead of the first internal electrode is connected to the second external electrode, and the eighteenth lead of the second internal electrode is connected to the fifth external electrode.

11. The multilayer ceramic capacitor of claim 10, wherein the first internal connection conductor is connected to the second internal electrode via the fifth external electrode and connected to two second internal connection conductors via the fourth and sixth external electrodes.

12. The multilayer ceramic capacitor of claim 10, wherein one ends of two second internal connection conductors are connected to the first internal connection conductor via the fourth and sixth external electrodes, and the other ends of the two second internal connection conductors are connected to the first and third external electrodes.

13. A multilayer ceramic capacitor comprising:
a ceramic body including a plurality of dielectric layers and having first and second main surfaces opposing each other, first and second side surfaces opposing each other, and first and second end surfaces opposing each other;
a first internal electrode having a twenty-second lead exposed to the first main surface and a third internal electrode having a twenty-third lead exposed to the first main surface, the first and third internal electrodes being formed on one dielectric layer in the ceramic body, and a second internal electrode having a twenty-fourth lead exposed to the second main surface and a fourth internal electrode having a twenty-fifth lead exposed to the second main surface, the second and fourth internal electrodes being formed on another dielectric layer in the ceramic body;
a first resistor part including a first internal connection conductor formed in the ceramic body and having twenty-sixth and twenty-seventh leads exposed to the second main surface, a second resistor part including a second internal connection conductor formed in the ceramic body and having twenty-eighth and twenty-ninth leads exposed to the second main surface, and a third resistor part including a third internal connection conductor formed in the ceramic body and exposed to the first and second main surfaces;
a first dummy electrode formed in the ceramic body and exposed to the first main surface and the first end surface of the ceramic body and a second dummy electrode formed in the ceramic body and exposed to the first main surface and the second end surface of the ceramic body; and
first to sixth external electrodes formed on the first and second main surfaces of the ceramic body and electrically connected to the first and second internal electrodes and the first to third internal connection conductors, a first connection terminal formed on the first main surface and the first end surface of the ceramic body and connected to the first dummy electrode, and a second connection terminal formed on the first main surface and the second end surface of the ceramic body and connected to the second dummy electrode,
wherein the first and second internal electrodes form a first capacitor part, and the third and fourth internal electrodes form a second capacitor part, the first capacitor part and the first resistor part being connected in series to each other, and the second capacitor part and the second resistor part being connected in series to each other.

14. The multilayer ceramic capacitor of claim 13, wherein the twenty-second lead of the first internal electrode is connected to the first external electrode, the twenty-third lead of the third internal electrode is connected to the third external electrode, the twenty-fourth lead of the second internal electrode is connected to the fourth external electrode, and the twenty-fifth lead of the fourth internal electrode is connected to the sixth external electrode.

15. The multilayer ceramic capacitor of claim 14, wherein the first internal connection conductor is connected to the second internal electrode via the fourth external electrode and connected to the second internal connection conductor via the fifth external electrode.

16. The multilayer ceramic capacitor of claim 14, wherein the second internal connection conductor is connected to the first internal connection conductor via the fifth external electrode and connected to the fourth internal electrode via the sixth external electrode.

17. The multilayer ceramic capacitor of claim 14, wherein one end of the third internal connection conductor is connected to the first and second internal connection conductors via the fifth external electrode, and the other end of the third internal connection conductor is connected to the second external electrode.

18. A board having a multilayer ceramic capacitor, the board comprising:
a printed circuit board having first to fifth electrode pads formed thereon; and
the multilayer ceramic capacitor of claim 1 mounted on the printed circuit board.

19. The board of claim 18, wherein the fourth electrode pad contacts the first connection terminal.

20. The board of claim 18, wherein the fifth electrode pad contacts the second connection terminal.

21. The board of claim 18, wherein the first and fourth electrode pads contact each other, and the third and fifth electrode pads contact each other.

22. A board having a multilayer ceramic capacitor, the board comprising:
a printed circuit board having first to fifth electrode pads formed thereon; and
the multilayer ceramic capacitor of claim 5 mounted on the printed circuit board.

23. Aboard having a multilayer ceramic capacitor, the board comprising:
a printed circuit board having first to fifth electrode pads formed thereon; and
the multilayer ceramic capacitor of claim 9 mounted on the printed circuit board.

24. Aboard having a multilayer ceramic capacitor, the board comprising:
a printed circuit board having first to fifth electrode pads formed thereon; and
the multilayer ceramic capacitor of claim 13 mounted on the printed circuit board.
